(19) United States
(12) Patent Application Publication
(10) Pub. No.: US 2010/0006968 A1
(43) Pub. Date: Jan. 14, 2010

(54) Image sensors and methods of manufacturing the same

(75) Inventors: Kyung-ho Lee, Suwon-si (KR); Jung-chak Ahn, Yongin-si (KR); Yi-tae Kim, Hwaseong-si (KR); Wook Lee, Anyang-si (KR); Bum-suk Kim, Seoul (KR); Tae-sub Jung, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/458,011

(22) Filed: Jun. 29, 2009

(30) Foreign Application Priority Data
Jul. 11, 2008 (KR) 10-2008-0067817

(51) Int. Cl. H01L 31/0232; H01L 31/0224

(52) U.S. Cl. 257/432; 438/73; 257/E31.124; 257/E31.127

(57) ABSTRACT

Provided are image sensors and a methods of manufacturing image sensors. The image sensors may include a substrate, a pixel array region, and a peripheral circuit region. The substrate includes a first region and a second region. The pixel array region may be formed on the first region. The peripheral circuit region may be formed on the second region. The first region may be located higher than the second region. According to the image sensor and the method of manufacturing the same, the vertical height of the pixel array region is decreased as compared to the prior art, and thus the aspect ratio at the pixel array region is minimized. As a result, condensing efficiency the image sensor may be improved.

### CROSS-REFERENCE TO RELATED APPLICATIONS

This application claims the benefit of Korean Patent Application No. 10-2008-0067817, filed on Jul. 11, 2008, in the Korean Intellectual Property Office, the disclosure of which is incorporated herein in its entirety by reference.

### BACKGROUND

1. Field

Example embodiments relate to image sensors and methods of manufacturing the same, and more particularly, to image sensors with improved light condensing efficiency and a method of manufacturing the same.

2. Description of the Related Art

An image sensor is a device for converting optical information to electric signals. Examples of image sensors include charge coupled devices (CCD) and CMOS image sensors (CIS). A CIS has multiple advantages over a CCD. For example, a CIS device uses a simpler driving method, consumes less power, may integrate signal processing circuits into the CMOS circuit and may achieve reduced manufacturing costs by using standard CMOS processing technology. Furthermore, higher integration density can be achieved over CCD devices due to CMOS miniaturization capabilities. Thus, CIS are widely used in various fields. In a CIS device, each pixel of a pixel region includes a MOS transistor and outputs image signals sensed in a switching operation of the MOS transistor.

### SUMMARY

Example embodiments provide methods of manufacturing image sensors with improved light condensing efficiency. Example embodiments also provide image sensors manufactured according to the methods of manufacturing image sensors.

According to example embodiments, there is provided a method of manufacturing an image sensor, the method including forming a substrate having a first region and a second region, the first region formed higher than the second region, forming a pixel array region on the first region, and forming a peripheral circuit region on the second region.

The formation of the substrate may include etching the entire second region and forming an insulation layer in the etched second region. The etching may be performed when forming a plurality of trenches for forming an insulation layer in the first region. The formation of the insulation layer may further include forming a plurality of trenches for forming the insulation layer in the etched second region, performing CMP (chemical mechanical polishing), and etching on the entire second region to the top surface of the insulation layer in the plurality of trenches of the second region.

The formation of the substrate may further include forming an insulation layer in the first region. The formation of the substrate may include etching the entire second region and forming insulation layers in the first region and the etched second region. The formation of the insulation layers may include forming a plurality of trenches for forming the insulation layer in the first region and the etched second region, performing CMP, and etching the entire second region to the top surface of the insulation layer in the plurality of trenches in the second region.

The formation of the pixel array may be performed by repeatedly forming structures of the same pattern on the first region. The forming of the peripheral circuit region may be performed by either forming structures of random patterns or repeatedly forming structures of the same pattern on the second region.

According to example embodiments, there is provided an image sensor including a substrate having a first region and a second region, a pixel array region formed on the first region, and a peripheral circuit region formed on the second region, wherein the first region is located higher than the second region.

### BRIEF DESCRIPTION OF THE DRAWINGS

Example embodiments will be more clearly understood from the following brief description taken in conjunction with the accompanying drawings. FIGS. 1-6E represent non-limiting, example embodiments as described herein.

FIG. 1 is a cross-sectional view of an image sensor according to an example embodiment;

FIG. 2 is a flowchart of a method of manufacturing the image sensor shown in FIG. 1;

FIG. 3 is a flowchart of a method of manufacturing the substrate shown in FIG. 1, according the operation S210 of FIG. 2;

FIGS. 4A-4E are cross-sectional views of a method of manufacturing a substrate according to the method of FIG. 3;

FIG. 5 is a flowchart of a method of manufacturing the substrate shown in FIG. 1, according to the operation S210 of FIG. 2; and

FIGS. 6A-6E are cross-sectional views of a method of manufacturing a substrate according to the method of FIG. 5.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

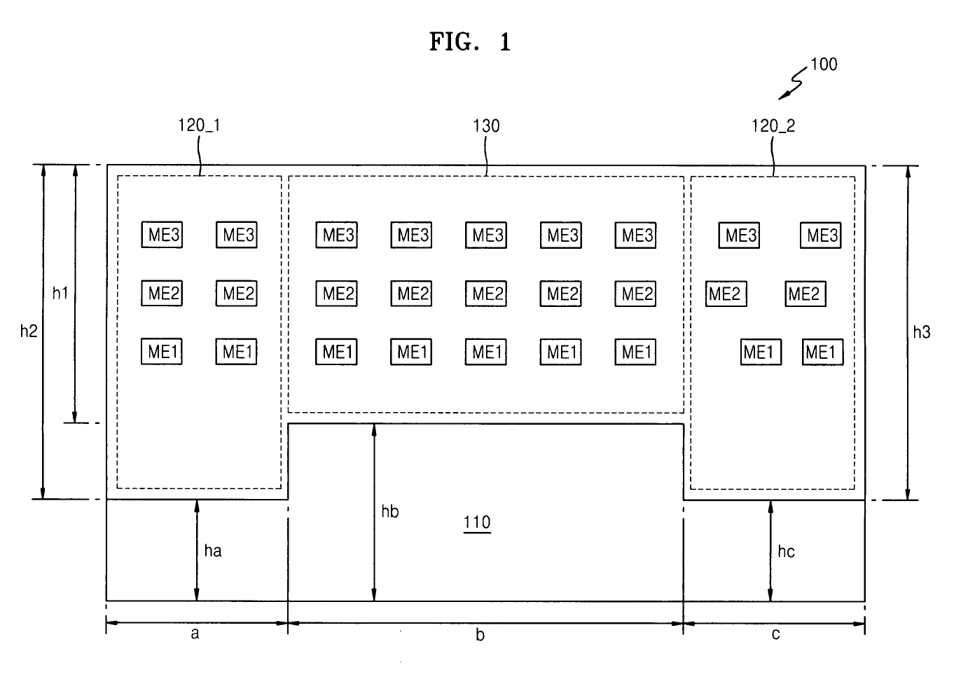

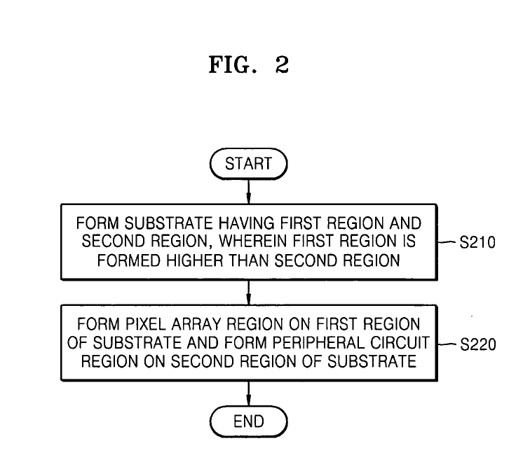

FIG. 1 is a cross-sectional view of an image sensor 100 according to an example embodiment. FIG. 2 is a flowchart of a method of manufacturing the image sensor of FIG. 1.

Referring to FIG. 1, the image sensor 100 may include a substrate 110, a pixel array region 130, and peripheral circuit regions 120_1 and 120_2. Although not shown in FIG. 1, the image sensor 100 may also include a plurality of photo diodes, a plurality of interlayer insulation layers, a plurality of color filters, and a plurality of micro lenses. The photo diodes may be formed on the substrate 110. The interlayer insulation layers and metal wirings ME1, ME2, and ME3 may also be formed on the substrate 110. The color filters may be formed on the topmost interlayer insulation layer, and the micro lenses may be formed on the color filters.

The substrate 110 may include a first region b having a height h_{b}, second region a having a height hₐ and second region c having a height h_{c}.

A method of manufacturing the substrate 110 with an uneven surface will be described below with reference to FIGS. 1-4E, and another method of manufacturing the substrate 110 with an uneven surface will be described below with reference to FIGS. 1-2 and 5-6E.

The pixel array region 130 may be formed on the first region b of the substrate 110, whereas the peripheral circuit regions 120_1 and 120_2 may be respectively formed on the second regions a and c of the substrate 110. The pixel array region 130 may include a plurality of pixels and structures having the same pattern may be repeatedly formed. Each of the peripheral circuit regions 120_1 and 120_2 may include at least one peripheral circuit, and may include a region in which structures having the same pattern are repeatedly formed or a region in which structures having random patterns may be formed.

According to at least one example embodiment, the first region b of the substrate 110 may located higher than the second regions a and c of the substrate 110 such that the height h_{b} is greater than the heights hₐ or h_{c}. As a result, the height h1 of the pixel array region 130 may be less than the height h2 or h3 of the peripheral circuit regions 120_1 and 120_2, and the aspect ratio of the pixel array region 130 may be less than the aspect ratio of the peripheral circuit regions 120_1 and 120_2. According to example embodiments, hₐ may equal h_{c} and h2 may equal h3.

The aspect ratio of the pixel array region refers to a ratio between the height of the pixel array region and a pixel pitch. In other words, the aspect ratio of the pixel array region is a value obtained by dividing the height h1 of the pixel array region 130, measured from the top surface of a substrate to the rear surface of a color filter, by a pixel pitch, which is a horizontal distance between pixels (not shown). Since structures having the same pattern may be repeatedly formed in the pixel array region 130, there may be no problem in manufacturing operations even if the height h1 of the pixel array region 130 is smaller than the height h2 and h3 of the peripheral circuit regions 120_1 and 120_2.

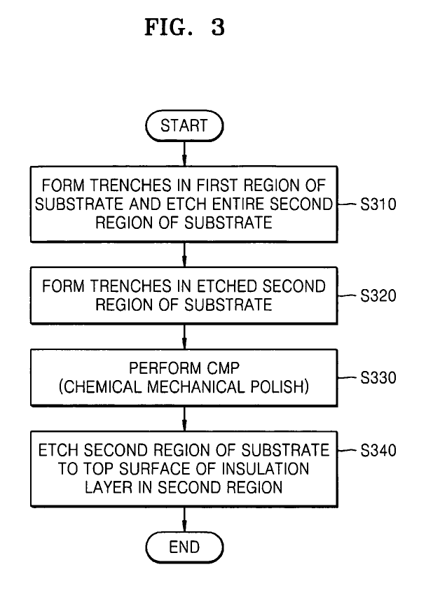

Referring to FIGS. 1 and 2, the substrate 110 may be formed to have the first region b and the second regions a and c, wherein the first region b may be located higher than the second regions a and c (operation S210). Embodiments of methods of forming the substrate 110 with uneven surfaces will be described below in detail with reference to FIGS. 3-6E. Embodiments shown in FIGS. 3-6E are merely example methods of forming the substrate 110 with an uneven surface, and example embodiments are not limited thereto. Thus, methods other than the methods explained with regard to FIGS. 3 through 6E are also included in the scope of example embodiments if a substrate substantially identical to the substrate 110 is formed. After the substrate 110 with uneven surface is formed, the pixel array region 130 may be formed on the first region b of the substrate 110, and the peripheral circuit regions 120_1 and 120_2 may be respectively formed on the second regions a and c of the substrate 110 (operation S220).

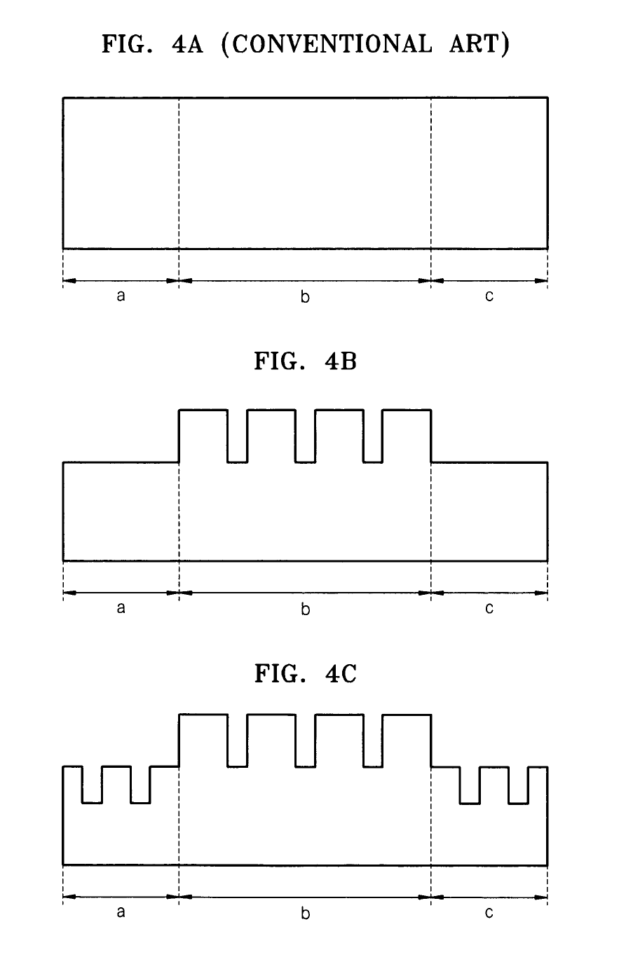

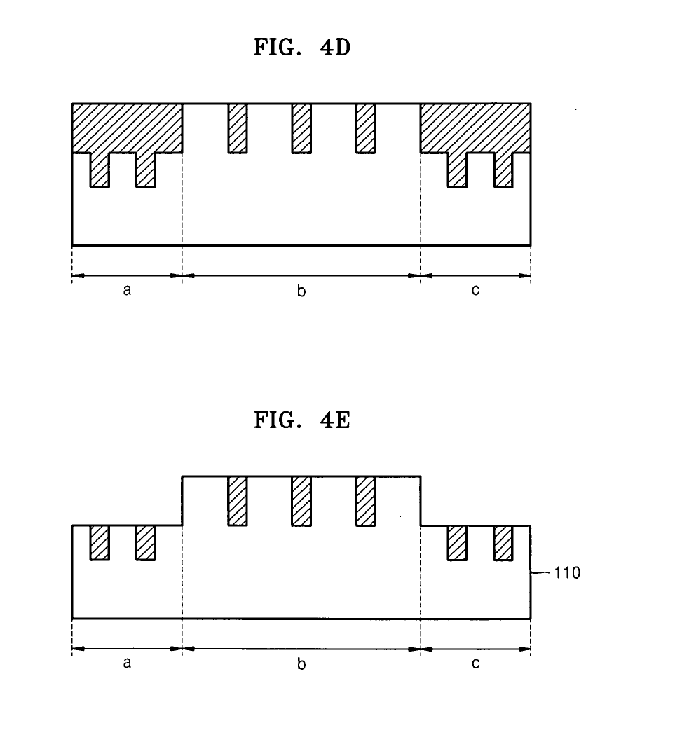

FIG. 3 is a flowchart of a method of manufacturing the substrate shown in FIG. 1, according the operation S210 of FIG. 2. FIGS. 4A-4E are cross-sectional views of a method of manufacturing a substrate according to the method of FIG. 3.

Referring to FIGS. 3-4E, FIG. 4A shows the shape of a general substrate in the conventional art. To form the substrate 110 with uneven surface, a plurality of trenches for forming an insulation layer may be formed in the first region b of the substrate shown in FIG. 4A, and the entire second regions a and c of the substrate may be etched (operation S310). After the operation S310, the shape of the substrate shown in FIG. 4A may be changed to that shown in FIG. 4B. A plurality of trenches for forming an insulation layer may be formed in the etched second regions a and c of the substrate of FIG. 4B (operation S320). After the operation S320, the shape of the substrate shown in FIG. 4B may be changed to that shown in FIG. 4C. Chemical mechanical polishing (CMP) may be performed on the substrate shown in FIG. 4C (operation S330). After the operation S330, the trenches of the first region b and the second regions a and c of the substrate shown in FIG. 4C may be filled with insulation materials as shown in FIG. 4D. In FIG. 4D, the insulation materials are indicated by angled hatching. The entire second regions a and c of the substrate shown in FIG. 4D may be etched in the top surface of the insulation layer of the second regions a and c (operation S340). After the operation S340, a substrate substantially identical to the substrate 110 of FIG. 1 may be formed.

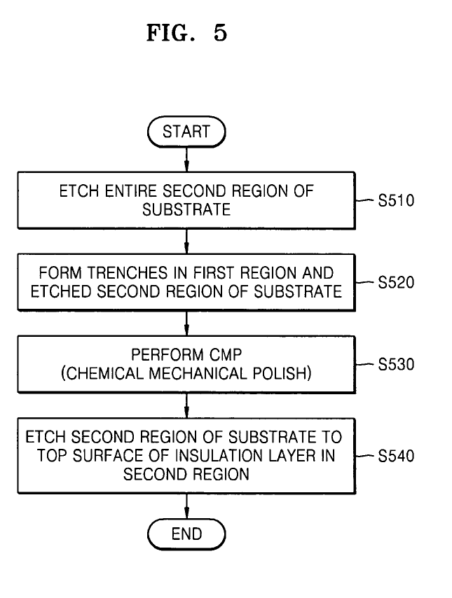

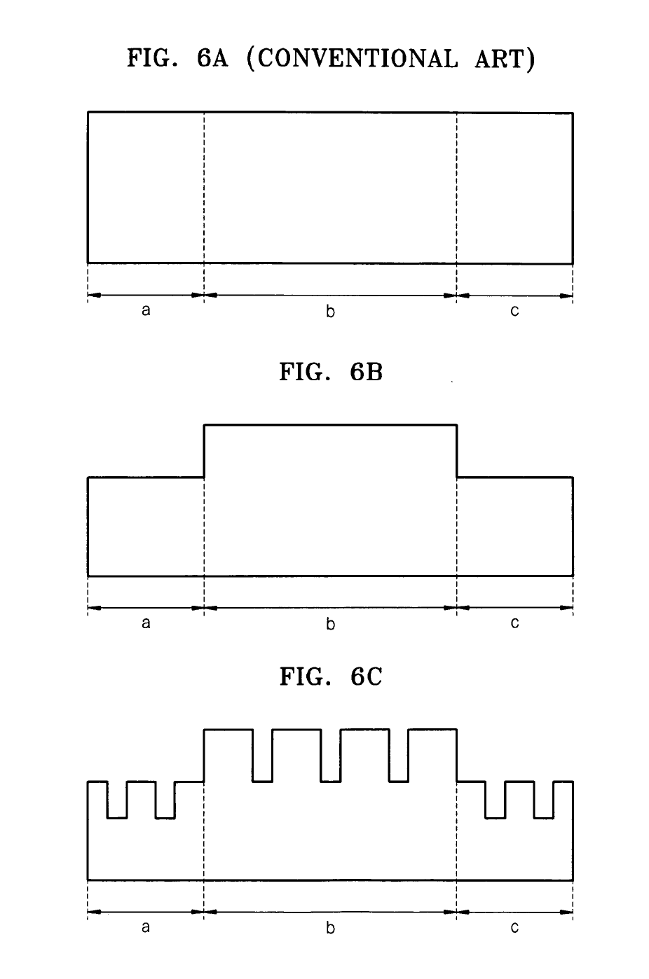

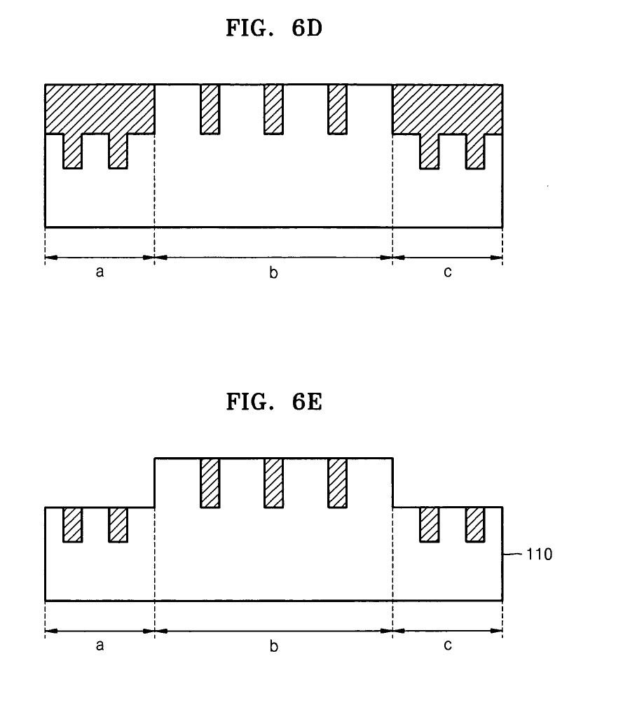

FIG. 5 is a flowchart of a method of manufacturing the substrate shown in FIG. 1, according to the operation S210 of FIG. 2. FIGS. 6A-6E are cross-sectional views of a method of manufacturing a substrate according to the method of FIG. 5. Referring to FIGS. 1-2 and 5-6E, FIG. 6A shows shape of a general substrate in the conventional art. To form the substrate 110 with an uneven surface, the entire second regions a and c of the substrate of FIG. 6A may be etched (operation S510). After the operation S510, the shape of the substrate shown in FIG. 6A may be changed to that shown in FIG. 6B. A plurality of trenches for forming an insulation layer may be formed in the first region b and the etched second regions a and c of the substrate of FIG. 6B (operation S520). After the operation S520, the shape of the substrate shown in FIG. 6B may be changed to that shown in FIG. 6C. Chemical mechanical polishing (CMP) may be performed on the substrate shown in FIG. 6C (operation S330). After the operation S330, trenches of the first region b and the second regions a and c of the substrate shown in FIG. 6C may be filled with insulation materials as shown in FIG. 6D. In FIG. 6D, the insulation materials are indicated by angled hatching. The entire second regions a and c of the substrate shown in FIG. 6D may be etched in the top surface of the insulation layer of the second regions a and c (operation S540). After the operation S540, a substrate substantially identical to the substrate 110 of FIG. 1 may be formed.

The embodiment shown in FIGS. 3-4E and the embodiment shown in FIGS. 5-6E show methods of forming uneven substrates when insulation layers are formed. However, as described above, example embodiments are not limited to the embodiments shown in FIGS. 3-6E, and methods other than the methods shown in FIGS. 3-6E may also be included in the scope of the claims if a substrate substantially identical to the substrate 110 may be formed.

While example embodiments have been particularly shown and described, it will be understood by one of ordinary skill in the art that variations in form and detail may be made therein without departing from the spirit and scope of the claims.

What is claimed is:

1. A method of manufacturing an image sensor, the method comprising:
forming a substrate having a first region and a second region, the first region formed higher than the second region;
forming a pixel array region on the first region; and
forming a peripheral circuit region on the second region.

2. The method of claim 1, wherein the forming a substrate comprises:
etching the entire second region; and
forming an insulation layer in the etched second region.

3. The method of claim 2, wherein the etching is performed when forming a plurality of trenches in the first region.

4. The method of claim 2, wherein the forming an insulation layer further comprises:
forming a plurality of trenches in the etched second region;
forming an insulation material in the plurality of trenches;
performing CMP (chemical mechanical polishing) on the substrate; and
etching the entire second region to the top surface of the insulation layer in the plurality of trenches of the second region.

5. The method of claim 2, wherein the forming a substrate further comprises forming an insulation layer in the first region.

6. The method of claim 1, wherein the forming a substrate comprises:
etching the entire second region to have a surface lower than the first region; and
forming insulation layers in the first region and the etched second region.

7. The method of claim 6, wherein the forming insulation layers comprises:
forming a plurality of trenches in the first region and the etched second region;
performing CMP on the substrate; and
etching the entire second region to the top surface of the insulation layer in the plurality of trenches in the second region.

8. The method of claim 1, wherein the forming a pixel array region is performed by repeatedly forming structures of a same pattern on the first region.

9. The method of claim 1, wherein the forming a peripheral circuit region is performed by one of: (1) forming structures of different patterns on the second region, and (2) repeatedly forming structures of a same pattern on the second region.

10. An image sensor comprising:
a substrate having a first region and a second region, the first region being thicker than the second region;
a pixel array region formed on the first region; and
a peripheral circuit region formed on the second region.

11. The image sensor of claim 10, wherein the first region includes a first region insulation layer.

12. The image sensor of claim 11, wherein the second region includes a second region insulation layer.

13. The image sensor of claim 12, wherein the first and second insulation layers include a plurality of trenches filled with insulation material.

14. The image sensor of claim 10, wherein the pixel array is a repeating structure of a same pattern.

15. The image sensor of claim 10, wherein the peripheral circuit region includes one of (1) a repeating structure of a same pattern, and (2) a repeating structure of different patterns.

16. The image sensor of claim 10, wherein an aspect ratio of the pixel array region is less than an aspect ratio of the peripheral circuit region.

17. The image sensor of claim 12, further comprising:
a plurality of photo diodes;
a plurality of interlayer insulation layers; and
a plurality of metal wirings.

18. The image sensor of claim 17, wherein the plurality of photo diodes, the plurality of interlayer insulation layers and the plurality of metal wirings are on the substrate.

19. The image sensor of claim 18, further comprising:
a plurality of color filters; and
a plurality of micro lenses,
wherein the plurality of color filters are on the top most of the interlayer insulation layers, and
the micro lenses are on the color filters.

20. The image sensor of claim 10, wherein the first region and the second region are separated.
